(19) United States
(12) Patent Application Publication
(10) Pub. No.: US 2020/0339611 A1
(43) Pub. Date: Oct. 29, 2020

(54) WATER-REPELLENT PROTECTIVE FILM-FORMING AGENT, WATER-REPELLENT PROTECTIVE FILM-FORMING CHEMICAL SOLUTION, AND WAFER SURFACE TREATMENT METHOD

(71) Applicant: CENTRAL GLASS COMPANY, LIMITED, Ube-shi, Yamaguchi (JP)

(72) Inventors: Yuzo OKUMURA, Ube-shi, Yamaguchi (JP); Katsuya KONDO, Auderghem (BE); Shuhei YAMADA, Ube-shi, Yamaguchi (JP); Atsushi RYOKAWA, Ichikawa-shi, Chiba (JP); Yuki FUKUI, Ube-shi, Yamaguchi (JP)

(21) Appl. No.: 16/962,164

(22) PCT Filed: Feb. 5, 2019
(86) PCT No.: PCT/JP2019/003965

§ 371 Date: Jul. 14, 2020

(30) Foreign Application Priority Data
Feb. 13, 2018 (JP) 2018-023330

(51) Int. Cl. C07F 7/10; C09D 5/00; H01L 21/304

(52) U.S. Cl. CPC C07F 7/10; H01L 21/304; C09D 5/00

(57) ABSTRACT

The present invention is directed to a novel water-repellent protective film-forming agent and a novel water-repellent protective film-forming liquid chemical, each of which is for forming a water-repellent protective film on a silicon element-containing surface of a wafer, and a method of surface-treating a wafer with the use of the agent in liquid form or the liquid chemical. The water-repellent protective film-forming agent according to the present invention includes at least one kind of silicon compound selected from the group consisting of guanidine derivatives of the following general formula [1] and amidine derivatives of the following general formula [2].

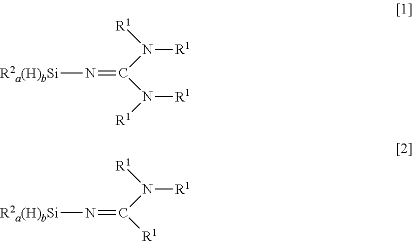

### FIELD OF THE INVENTION

The present invention relates to a water-repellent protective film-forming agent and a water-repellent protective film-forming liquid chemical, each of which is for forming a water-repellent protective film on a surface of a wafer, and a method of surface-treating a wafer with the use of the agent in liquid form or the liquid chemical.

### BACKGROUND ART

It is required that semiconductor devices for network applications and digital home appliances have higher performance, higher functionality and lower power consumption. Accordingly, the fine processing of circuit patterns has been pursued. With the fine processing of circuit patterns, however, the occurrence of pattern collapses in the circuit patterns is becoming a problem. The manufacturing of the semiconductor device makes great use of a cleaning process for removal of particles and metal impurities. Eventually, the cleaning process occupies 30 to 40% of the entire semiconductor manufacturing process. The pattern collapse is a phenomenon in which the pattern collapses due to the passage of a gas-liquid interface through the pattern after cleaning or rinsing in the cleaning process when the aspect ratio of the pattern becomes high with the fine patterning of the semiconductor device. The designs of the patterns have to be changed in order to prevent the occurrence of pattern collapses. Further, the occurrence of pattern collapses leads to a deterioration in manufacturing yield. It is thus demanded to develop a technique for preventing a pattern collapse during the cleaning process.

The formation of a water-repellent protective film on a surface of the pattern is known as an effective technique for preventing a pattern collapse. It is necessary to perform such water repellent treatment without drying the surface of the pattern. The water-repellent protective film is hence formed by supplying a water-repellent protective film-forming liquid chemical to the surface of the pattern on which a cleaning liquid etc. is retained and then replacing the cleaning liquid etc. with the liquid chemical.

The present applicant has disclosed, in Patent Document 1, a silicon wafer cleaning agent used for, in the manufacturing of a silicon wafer having a fine uneven pattern on a surface thereof, improving a cleaning process in which a pattern collapse is likely to occur, and a method of cleaning a wafer with the use of the silicon wafer cleaning agent, wherein the silicon wafer cleaning agent includes a water-based cleaning liquid and a water-repellent cleaning liquid for imparting water repellency to at least a recess portion of the uneven pattern during the cleaning process; and wherein the water-repellant cleaning liquid consists of a water-repellant compound with a hydrophobic group and a reactive moiety chemically bondable to Si of the silicon wafer, or comprises an organic solvent and 0.1 mass % or more of the water-repellent compound based on 100 mass % of the total amount of the water-repellent cleaning liquid, whereby, on the assumption that water is retained in the recess portion of the silicon wafer surface which has been made water repellent by treatment with the water-repellant cleaning liquid, the silicon wafer surface exhibits a capillary force of 2.1 MN/m² or less. In the water-repellant cleaning liquid, the water-repellent compound used is at least one selected from the group consisting of compounds of the following general formulas [A], [B] and [C].

(R¹)ₐSi(CH₃)_{b}H_{c}X_{4-a-b-c} [A]

[R²Si(CH₃)_{2-d}H_{d}]ₑNH₃₋ₑ [B]

R³Si(CH₃)₂Y [C]

In the general formulas [A], [B] and [C], R′, R² and R³ are each independently a monovalent organic group having a hydrocarbon structure of 1 to 18 carbon atoms or a monovalent organic group having a perfluoroalkyl chain of 1 to 8 carbon atoms; X is a chlorine atom, an isocyanate group or an alkoxy group; Y is an organic group whose atom bonded to Si is nitrogen; a is an integer of 1 to 3; b and c are each an integer of 0 to 2; the sum of a, b and c is 1 to 3; d is an integer of 0 to 2; and e is an integer of 1 to 3.

The present applicant has further disclosed, in Patent Document 2, a water-repellent protective film-forming liquid chemical used for, in the manufacturing of a water having on a surface thereof a fine uneven pattern at least a part of which contains a silicon element, forming a water-repellent protective film on the uneven pattern of the wafer surface to improve a cleaning process in which a pattern collapse is likely to occur, without causing a deterioration in throughput, and a method of cleaning a wafer with the use of the liquid chemical. More specifically, the liquid chemical is used for, in a process of cleaning a water having on a surface thereof a fine uneven pattern at least a part of which contains a silicon element, forming a water-repellent protective film on at least a recess portion of the uneven pattern, wherein the liquid chemical comprises a silicon compound A of the following general formula [D], an acid capable of donating a proton to the silicon compound A and/or an acid capable of accepting a proton from the silicon compound A; and wherein the total amount of water contained in raw materials of the liquid chemical is 5000 ppm or less based on the total amount of the raw materials.

R⁴_{f}Si(H)_{g}(Z)_{4-f-g} [D]

In the general formula [D], R⁴ is each independently at least one group selected from a monovalent organic group having a hydrocarbon structure of 1 to 18 carbon atoms and a monovalent organic group having a fluoroalkyl chain of 1 to 8 carbon atoms; Z is each independently at least one group selected from a halogen atom, a monovalent organic group whose atom bonded to Si is oxygen or nitrogen and a nitrile group; f is an integer of 1 to 3; g is an integer of 0 to 2; the sum off and g is 3 or less.

### PRIOR ART DOCUMENTS

### Patent Documents

Patent Document 1: Japanese Laid-Open Patent Publication No. 2010-192878

Patent Document 2: Japanese Laid-Open Patent Publication No. 2012-033873

### SUMMARY OF THE INVENTION

### Problems to be Solved by the Invention

The combinations of materials and film configurations of semiconductor wafers are increasing with improvements in device performance and functionality. In the case of wafers whose surfaces contain a silicon element, circuit patterns are formed on the wafers by using various materials such as not only silicon element-containing layer but also metal wiring layer, electrode layer, capacitor layer, dielectric layer, device forming layer etc. Against the ever-increasing large number of combinations of semiconductor wafer configurations, it is desired to secure a wide choice of options including as many novel water-repellent protective film-forming liquid chemicals as possible in addition to conventional water-repellent protective film-forming liquid chemicals such that suitable liquid chemicals can be applied to form water-repellent protective films on wafer surfaces and prevent the occurrence of pattern collapses during cleaning processes.

Further, there is a possibility that, depending on the configuration of the wafer, the constituent component of the water-repellent protective film-forming liquid chemical causes an adverse effect on the wafer. In the case of using a silane compound such as chlorosilane, bromosilane or iodosilane, for example, the wafer may be adversely affected by a chlorine atom, bromine atom or iodine atom depending on the wafer configuration. The water-repellant cleaning liquid of Patent Document 1 can impart good water repellency to the surface of the silicon wafer, but has a problem that, when a chlomsilane compound is used as the water-repellent compound in the water-repellant cleaning liquid as in Example 22 of Patent Document 1, the wafer may be adversely affected by a chlorine atom depending on the wafer configuration. There are cases where a protective film-forming component with no chlorine atom is preferable.

The protective film-forming liquid chemical of Patent Document 2 can also impart good water repellency to the silicon element-containing surface of the wafer, but has a problem that, during preparation of the liquid chemical, it is necessary to accurately weigh the silicon compound A for forming the protective film and the acid for promoting the formation of the protective film and thereby accurately control the concentrations of the silicon compound A and the acid. From the viewpoint of loads in liquid chemical preparation operation and concentration control, preferable is a water-repellent protective film-forming liquid chemical which does not essentially require a protective film formation-promoting component.

In view of the foregoing, it is an object of the present invention to provide a novel water-repellent protective film-forming agent (hereinafter also simply referred to as “protective film-forming agent” or “agent”) or novel water-repellent protective film-forming liquid chemical (hereinafter also simply referred to as “protective film-forming liquid chemical” or “liquid chemical”) which uses a water-repellent protective film-forming component with no chlorine atom and does not essentially require a protective film formation-promoting component, and a method of surface-treating a wafer with the use of the agent in liquid form or the liquid chemical.

### Means for Solving the Problems

One aspect of the present invention is a water-repellent protective film-forming agent for forming a water-repellent protective film on a silicon element-containing surface of a wafer, comprising at least one kind of silicon compound selected from the group consisting of guanidine derivatives of the following general formula [1] and amidine derivatives of the following general formula [2].

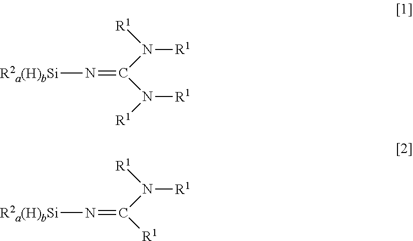

In the general formulas [1] and [2], R¹ is each independently a hydrogen atom, a —C≡N group, a —NO₂ group or a hydrocarbon group in which a part or all of hydrogen atoms may be substituted with a fluorine atom; the hydrocarbon group as R¹ may contain an oxygen atom and/or a nitrogen atom; R² is a monovalent hydrocarbon group of 1 to 18 carbon atoms in which a part or all of hydrogen atoms may be substituted with a fluorine atom; a is an integer of 1 to 3; b is an integer of 0 to 2; and the sum of a and b is 3.

It is preferable that, in the general formulas [1] and [2], b is 0 so as to readily maintain water repellency during the after-mentioned cleaning process after the formation of the protective film. In this case, it is further preferable that at least two of three R² in the general formulas [1] and [2] are methyl groups so as to uniformly form the protective film. The combination of two methyl groups and one linear alkyl group is particularly preferable as R² for more uniform formation of the protective film.

It is preferable that R¹ in the general formulas [1] and [2] is each independently selected from the group consisting of a hydrogen atom, an alkyl group of 1 to 6 carbon atoms and an alkoxy group of 1 to 6 carbon atoms.

It is preferable that a compound by-produced upon the acceptance of a proton by the silicon compound is liquid at 25° C. and 1.0 atmospheric pressure.

The silicon compound is preferably of the general formula [1].

More preferably, the silicon compound is of the general formula [1] where all of R¹ are methyl groups; a is 3; b is 0; two of three R² are methyl groups; and the remaining one of R² is a monovalent hydrocarbon groups of 1 to 18 carbon atoms in which a part or all of hydrogen atoms may be substituted with a fluorine atom.

Another aspect of the present invention is a water-repellent protective film-forming liquid chemical comprising: the above-mentioned water-repellent protective film-forming agent; and an organic solvent.

The concentration of the water-repellent protective film-forming agent is preferably 0.01 to 25 mass % based on 100 mass % of the total amount of the water-repellent protective film-forming agent and the organic solvent.

The organic solvent is preferably an aprotic solvent.

It is preferable that the total amount of water contained in the water-repellent protective film-forming agent and the organic solvent before preparation of the water-repellent protective film-forming liquid chemical is 5000 mass ppm or less based on the total amount of the water-repellent protective film-forming agent and the organic solvent.

Still another aspect of the present invention is a method of surface-treating a silicon element-containing wafer with the use of the above-mentioned water-repellent protective film-forming agent in liquid form.

Yet another aspect of the present invention is a method of surface-treating a silicon element-containing wafer with the use of the above-mentioned water-repellent protective film-forming liquid chemical.

### Effects of the Invention

The water-repellent protective film-forming agent or water-repellent protective film-forming liquid chemical according to the present invention forms a water-repellent protective film on a silicon element-containing wafer surface so as to decrease the capillary force of an uneven pattern of the wafer surface and thereby exhibit a pattern collapse preventing effect, and secures a new choice of options against the ever-increasing large number of combinations of semiconductor wafer configurations.

### BRIEF DESCRIPTION OF DRAWINGS

FIG. 1 is a schematic perspective view of a wafer 1 having on a surface thereof a fine uneven pattern 2.

FIG. 2 is a view showing a part of a-a′ cross section of FIG. 1.

FIG. 3 is a schematic view showing a state where a water-repellent protective film-forming agent in liquid form or protective film-forming liquid chemical 8 is retained in recess portions 4 of the pattern during cleaning process.

FIG. 4 is a schematic view showing a state where a liquid is retained in recess portions 4 of the pattern on which a protective film has been formed.

### DETAILED DESCRIPTION OF THE EMBODIMENTS

1. Water-Repellent Protective Film-Forming Agent and Water-Repellent Protective Film-Forming Liquid Chemical

(1) Silicon Compound

The water-repellent protective film-forming agent according to the present invention includes at least one kind of silicon compound selected from the group consisting of guanidine derivatives of the above-indicated general formula [I] and amidine derivatives of the above-indicated general formula [2].

In the general formulas [1] and [2], R² is a water-repellent functional group. Each of a guanidyl group of the guanidine derivative and an amidynyl group of the amidine derivative reacts with a silanol group of the wafer surface. By such reaction, a moiety of the silicon compound containing the water-repellent functional group is fixed to the wafer surface whereby a water-repellent protective film is formed on the wafer surface.

Herein, the guanidine derivative of the general formula [1] and the amidine derivative of the general formula [2] are liquid at 25° C. and 1.0 atmospheric pressure. In the case of treating the silicon element-containing wafer surface with the use of the water-repellent protective film-forming agent in liquid form, it is preferable to adjust the viscosity of the water-repellent protective film-forming agent in liquid form by controlling the temperature thereof.

The hydrocarbon group as R¹ may have a linear or branched structure as exemplified by methyl, ethyl, propyl, butyl etc. or may have a cyclic structure as exemplified by cyclopropyl, cyclobutyl, cyclopentyl, cyclohexyl etc. A part or all of hydrogen atoms of the hydrocarbon group may be substituted with a fluorine atom.

The hydrocarbon group as R¹ may contain an oxygen atom. In this case, the hydrocarbon group can be exemplified by linear, branched or cyclic alkoxy groups such as methoxy, ethoxy, propoxy and butoxy. The oxygen atom may be present in the form of an ether bond between carbon atoms of the hydrocarbon group.

The hydrocarbon group as R¹ may contain a nitrogen atom. In this case, the hydrocarbon group can be exemplified by those containing primary to tertiary amino substituents.

Specific examples of the guanidine derivative of the general formula [1] include: those having an alkyl group as R², such as 2-trimethylsilyl-1,1,3,3-tetramethylguanidine, 2-ethyldimethylsilyl-1,1,3,3-tetramethylguanidine, 2-diethylmethylsilyl-1,1,3,3-tetramethylguanidine, 2-trimethylsilyl-1,1,3,3-tetramethylguanidine, 2-propyldimethylsilyl-1,1,3,3-tetramethylguanidine, 2-dipropylmethylsilyl-1,1,3,3-tetramethylguanidine, 2-tripropylsilyl-1,1,3,3-tetramethylguanidine, 2-butyldimethylsilyl-1,1,3,3-tetramethylguanidine, 2-pentyldimethylsilyl-1,1,3,3-tetramethylguanidine, 2-hexyldimethylsilyl-1,1,3,3-tetramethylguanidine, 2-heptyldimethyl-1,1,3,3-tetramethylguanidine, 2-octyldimethylsilyl-1,1,3,3-tetramethylguanidine, 2-nonyldimethylsilyl-1,1,3,3-tetramethylguanidine, 2-decyldimethylsilyl-1,1,3,3-tetramethylguanidine, 2-undecyldimethylsilyl-1,1,3,3-tetramethylguanidine, 2-dodecyldimethylsilyl-1,1,3,3-tetramethylguanidine, 2-tridecyldimethylsilyl-1,1,3,3-tetramethylguanidine, 2-tetradecyldimethylsilyl-1,1,3,3-tetramethylguanidine, 2-pentadecyldimethylsilyl-1,1,3,3-tetramethylguanidine, 2-hexadecyldimethylsilyl-1,1,3,3-tetramethylguanidine, 2-heptadecyldimethylsilyl-1,1,3,3-tetramethylguanidine, 2-octadecyldimethylsilyl-1,1,3,3-tetramethylguanidine, 2-dimethylsilyl-1,1,3,3-tetramethylguanidine, 2-methylsilyl-1,1,3,3-tetramethylguanidine, 2-diethylsilyl-1,1,3,3-tetramethylguanidine, 2-ethylsilyl-1,1,3,3-tetramethylguanidine, 2-ethylmethylsilyl-1,1,3,3-tetramethylguanidine and 2-dipropylsilyl-1,1,3,3-tetramethylguanidine; those having the combination of a fluoroalkyl group and an alkyl group as R², such as 2-trifluoropropyldimethylsilyl-1,1,3,3-tetramethylguanidine, 2-pentafluorobutyldimethylsilyl-1,1,3,3-tetramethylguanidine, 2-heptafluoropentyldimethylsilyl-1,1,3,3-tetramethylguanidine, 2-nonafluorohexyldimethylsilyl-1,1,3,3-tetramethylguanidine, 2-undecafluoroheptyldimethylsilyl-1,1,3,3-tetramethylguanidine, 2-tridecafluorooctyldimethylsilyl-1,1,3,3-tetramethylguanidine, 2-pentadecafluorononyldimethylsilyl-1,1,3,3-tetramethylguanidine, 2-heptadecafluorodecyldimethylsilyl-1,1,3,3-tetramethylguanidine and 2-trifluoropropylmethylsilyl-1,1,3,3-tetramethylguanidine; and those obtained by independently replacing each of methyl groups of the 1,1,3,3-tetramethylguanidyl moieties of the aforementioned guanidine derivatives are each independently replaced with a hydrogen atom, a —C≡N group, a —NO₂ group or a hydrocarbon group other than methyl in which a part or all of hydrogen atoms may be substituted with a fluorine atom. The hydrocarbon group may contain an oxygen atom and/or a nitrogen atom.

Specific examples of the amidine derivative of the general formula [2] include those obtained by replacing guanidyl groups of the above-exemplified guanidine derivatives of the general formula [1] with an amidynyl group.

In terms of the water repellency imparting effect, it is preferable that R¹ in the general formulas [1] and [2] is an electron-donating group. Among others, R¹ is preferably selected from a hydrogen atom, an alkyl group of 1 to 6 carbon atoms and an alkoxy group of 1 to 6 carbon atoms. Specific examples of the alkyl group of 1 to 6 carbon atoms include methyl, ethyl, n-propyl, isopropyl, cyclopropyl, n-butyl, isobutyl, sec-butyl, tert-butyl, cyclobutyl, n-pentyl, cyclopentyl, n-hexyl and cyclohexyl. Specific examples of the alkoxy group of 1 to 6 carbon atoms include methoxy, ethoxy, n-propyloxy, isopropyloxy, n-butyloxy, isobutyloxy, sec-butyloxy, tert-butyloxy, n-pentyloxy and n-hexyloxy.

Further, it is preferable that b in the general formulas [1] and [2] is 0 so as to readily maintain water repellency during the after-mentioned cleaning process after the formation of the protective film. In this case, it is further preferable that at least two of three R² in the general formulas [1] and [2] are methyl so as to uniformly form the protective film. For more uniform formation of the protective film, the combination of two methyl groups and one linear alkyl group is particularly preferable as R².

Furthermore, it is preferable that a compound by-produced upon the acceptance of a proton by the silicon compound is liquid at 25° C. and 1.0 atmospheric pressure in terms of the cleanliness of the wafer surface during the surface treatment, the cleanliness and stability of the water-repellent protective film-forming agent in liquid form or the water-repellent protective film-forming liquid chemical and the cleanliness of the piping for discharge of the agent in liquid form or the liquid chemical after the surface treatment (hereinafter generically referred to as “waste liquid”). For example, 1,1,3,3-tetramethylguanidine, which is liquid at 25° C. and 1.0 atmospheric pressure, is formed as a by-product resulting from the acceptance of a proton by the silicon compound of the general formula [1] where all of R¹ are methyl.

Preferably, the silicon compound is of the general formula [1] so as to obtain a good water repellency imparting effect.

Since the above-described silicon compound is liquid at 25° C. and 1.0 atmospheric pressure, a liquid consisting of the silicon compound is applicable as the water-repellent protective film-forming agent to the wafer surface. It is feasible to apply the silicon compound in liquid form to the wafer surface by controlling the temperature of the agent and thereby adjusting the viscosity of the agent. Alternatively, it is feasible to dissolve and dilute the silicon compound in liquid form with an organic solvent and apply the resulting liquid chemical to the water surface.

(2) Organic Solvent

In the water-repellent protective film-forming liquid chemical according to the present invention, the silicon compound is diluted with the organic solvent.

The concentration of the silicon compound is preferably 0.01 to 25 mass %, based on 100 mass % of the total amount of the silicon compound and the organic solvent, so as to facilitate uniform formation of the protective film on the silicon element-containing wafer surface. When the concentration of the silicon compound is lower than 0.01 mass %, the water repellency imparting effect of the liquid chemical tends to be insufficient. In terms of the cost, it is favorable that the concentration of the component (I) is 25 mass % or lower. The concentration of the component (I) is more preferably 0.1 to 15 mass %, still more preferably 0.5 to 10 mass %.

As the organic solvent in the water-repellent protective film-forming liquid chemical, suitably usable are aprotic solvents such as hydrocarbons, esters, ethers, ketones, halogen-containing solvents, sulfoxide solvents, lactone solvents, carbonate solvents, OH-free polyol derivatives, NH-free nitrogen-containing solvents and silicone solvents, thiols and any mixture thereof. Among others, the organic solvent is preferably selected from hydrocarbons, esters, ethers, halogen-containing solvents, OH-free polyol derivatives and any mixture thereof so as to form the water-repellent protective film on the silicon element-containing wafer surface in a short time.

Examples of the hydrocarbons include hexane, heptane, octane, nonane, decane, dodecane, isododecane, tetradecane, hexadecane, octadecane, eicosane, cyclohexane, methylcyclohexane, decalin, benzene, toluene, xylene and diethylbenzene.

Examples of the esters include ethyl acetate, propyl acetate, butyl acetate and ethyl acetoacetate.

Examples of the ethers include diethyl ether, dipropyl ether, ethyl butyl ether, dibutyl ether, ethyl amyl ether, diamyl ether, methyl cyclopentyl ether, ethyl hexyl ether, dihexyl ether, dioctyl ether, diphenyl ether, tetrahydrofuran, dioxane, methyl perfluoropropyl ether, methyl perfluorobutyl ether, ethyl perfluorobutyl ether, methyl perfluorohexyl ether and ethyl perfluorohexyl ether.

Examples of the ketones include acetone, acetylacetone, methyl ethyl ketone, methyl propyl ketone, methyl butyl ketone, cyclohexanone and isophorone.

Examples of the halogen-containing solvents include: perfluorocarbons such as perfluorooctane, perfluorononane, perfluorocyclopentane, perfluorocyclohexane and hexafluorobenzene; hydrofluorocarbons such as 1,1,1,3,3-pentafluorobutane, octafluorocyclopentane, 2,3-dihydrodecafluoropentane and Zeorora H (available from Zeon Corporation); hydrofluoroethers such as methyl perfluoroisobutyl ether, methyl perfluorobutyl ether, ethyl perfluorobutyl ether, ethyl perfluoroisobutyl ether, Asahiklin AE-3000 (available from Asahi Glass Co., Ltd.), Novec 7100, Novec 7200, Novec 7300 and Novec 7600 (each available from 3M Company); chlorocarbons such as tetrachloromethane; hydrochlorocarbons such as chloroform; chlorofluorocarbons such as dichlorodifluoromethane; hydrochlorofluorocarbons such as 1,1-dichloro-2,2,3,3,3-pentafluoropropane, 1,3-dichloro-1,1,2,2,3-pentafluoropropane, 1-chloro-3,3,3-trifluoropropene and 1,2-dichloro-3,3,3-trifluoropropene; perfluoroethers; and perfluoropolyethers.

Examples of the sulfoxide solvents include dimethyl sulfoxide.

Example of the lactone solvents include γ-butyrolactone, γ-valerolactone, γ-hexanolactone, γ-heptanolactone, γ-octanolactone, γ-nonanolactone, γ-decanolactone, γ-undecanolactone, γ-dodecanolactone, δ-valerolactone, δ-hexanolactone, δ-octanolactone, δ-nonanolactone, δ-decanolactone, δ-undecanolactone, δ-dodecanolactone and ε-hexanolactone.

Examples of the carbonate solvents include dimethyl carbonate, ethyl methyl carbonate, diethyl carbonate and propylene carbonate.

Examples of the OH-free polyol derivatives include ethylene glycol dimethyl ether, ethylene glycol diethyl ether, ethylene glycol dibutyl ether, ethylene glycol monomethyl ether acetate, ethylene glycol monoethyl ether acetate, ethylene glycol monobutyl ether acetate, ethylene glycol diacetate, diethylene glycol dimethyl ether, diethylene glycol ethyl methyl ether, diethylene glycol diethyl ether, diethylene glycol butyl methyl ether, diethylene glycol dibutyl ether, diethylene glycol monomethyl ether acetate, diethylene glycol monoethyl ether acetate, diethylene glycol monobutyl ether acetate, diethylene glycol diacetate, triethylene glycol dimethyl ether, triethylene glycol diethyl ether, triethylene glycol dibutyl ether, triethylene glycol butyl methyl ether, triethylene glycol monomethyl ether acetate, triethylene glycol monoethyl ether acetate, triethylene glycol monobutyl ether acetate, triethylene glycol diacetate, tetraethylene glycol dimethyl ether, tetraethylene glycol diethyl ether, tetraethylene glycol dibutyl ether, tetraethylene glycol monomethyl ether acetate, tetraethylene glycol monoethyl ether acetate, tetraethylene glycol monobutyl ether acetate, tetraethylene glycol diacetate, propylene glycol dimethyl ether, propylene glycol diethyl ether, propylene glycol dibutyl ether, propylene glycol monomethyl ether acetate, propylene glycol monoethyl ether acetate, propylene glycol monobutyl ether acetate, propylene glycol diacetate, dipropylene glycol dimethyl ether, dipropylene glycol methyl propyl ether, dipropylene glycol diethyl ether, dipropylene glycol dibutyl ether, dipropylene glycol monomethyl ether acetate, dipropylene glycol monoethyl ether acetate, dipropylene glycol monobutyl ether acetate, dipropylene glycol diacetate, tripropylene glycol dimethyl ether, tripropylene glycol diethyl ether, tripropylene glycol dibutyl ether, tripropylene glycol monomethyl ether acetate, tripropylene glycol monoethyl ether acetate, tripropylene glycol monobutyl ether acetate, tripropylene glycol diacetate, tetrapropylene glycol dimethyl ether, tetrapropylene glycol monomethyl ether acetate, tetrapropylene glycol diacetate, butylene glycol dimethyl ether, butylene glycol monomethyl ether acetate, butylene glycol diacetate and glycerin triacetate.

Examples of the NH-free nitrogen-containing solvents include N,N-dimethylformamide, N,N-dimethylacetamide, N-methyl-2-pyrrolidone, triethylamine and pyridine.

Examples of the silicone solvents include hexamethyldisiloxane, octamethyltrisiloxane, decamethyltetrasiloxane and dodecamethylpentasiloxane.

Examples of the thiols include 1-hexanethiol, 2-methyl-1-pentanethiol, 3-methyl-1-pentanethiol, 4-methyl-1-pentanethiol, 2,2-dimethyl-1-butanethiol, 3,3-dimethyl-1-butanethiol, 2-ethyl-1-butanethiol, I-heptanethiol, benzyl thiol, I-octanethiol, 2-ethyl-1-hexanethiol, 1-nonanethiol, 1-decanethiol, 1-undecanethiol, 1-dodecanethiol and 1-tridecanethiol.

(3) Additives

In the present invention, the protective film-forming agent in liquid form or the protective film-forming liquid chemical may include additives such as a polymerization inhibitor, a chain transfer agent, an antioxidant etc. for further improvement in stability. Examples of the additives include 4-methoxyphenol, dibutylhydroxytoluene, butylated hydroxyanisole, 1,4-benzenediol, 2-(1,1-dimethylethyl)-1,4-benzenediol, 1,4-benzoquinone, 1-octanethiol, 1-nonanethiol, 1-decanethiol, 1-undecanethiol, 1-dodecanethiol, octyl-3,5-di-tert-butyl-4-hydroxy-hydrocinnamic acid (available as Irganox 1135 from BASF Corporation), 6-tert-butyl-2,4-xylenol and the like.

The additive is preferably liquid in terms of the cleanliness of the protective film-forming agent in liquid form or the protective film-forming liquid chemical. For example, 1-dodecanethiol, octyl-3,5-di-tert-butyl-4-hydroxy-hydrocinnamic acid (available as Irganox 1135 from BASF Corporation) and 6-tert-butyl-2,4-xylenol, each of which is liquid at 25° C. and 1.0 atmospheric pressure, are preferred.

Cleanliness of Liquid Chemical (Raw Materials)

It is preferable that the total amount of water contained in the water-repellent protective film-forming agent and the organic solvent before the preparation of the liquid chemical is 5000 mass ppm or less based on the total amount of the water-repellent protective film-forming agent and the organic solvent. When the total amount of water exceeds 5000 mass ppm, the water repellency imparting effect of the liquid chemical tends to be lowered. For this reason, it is preferable that the total amount of water is as small as possible. The total amount of water is more preferably 500 mass ppm or less, still more preferably 200 mass ppm or less. Due to the fact that the larger the amount of water present, the more likely the storage stability of the liquid chemical is to be deteriorated, it is preferable that the total amount of water is small. Thus, the total amount of water is particularly preferably 100 mass ppm or less, more particularly preferably 50 mass ppm or less. Although it is preferable that the total amount of water is as small as possible, the total amount of water may be 0.1 mass ppm or more as long as within the above range. Consequently, it is preferable that the silicon compound and the organic solvent before the preparation of the liquid chemical are low in water content.

The raw materials of the liquid chemical may be subjected, in advance, to distillation purification or dehydration treatment with a molecular sieve etc. such that the total amount of water in the raw materials are controlled to within the above range. Alternatively, the raw materials of the liquid chemical may be provided as commercially available products of low-water content grades.

It is also preferable that, in a particle measurement made in a liquid phase of the liquid chemical by a light scattering type in-liquid particle detector, the number of particles of diameter larger than 0.2 μm is 100 or less per 1 mL of the liquid chemical. When the number of particles of diameter larger than 0.2 μm exceeds 100 per 1 mL of the liquid chemical, there unfavorably occurs a risk that the particles cause damage to the pattern of the silicon element-containing wafer. This pattern damage can lead to a deterioration in device yield and reliability. When the number of particles of diameter larger than 0.2 μm is 100 or less per 1 mL of the liquid chemical, it is favorably possible to omit or reduce the cleaning of the wafer with a solvent or water after the formation of the protective film. Although it is preferable that the number of particles of diameter larger than 0.2 μm in the liquid chemical is as less as possible, the number of particles of diameter larger than 0.2 μm may be 1 or more per 1 mL of the liquid chemical as long as within the above range. In the present invention, the particle measurement in the liquid phase of the liquid chemical can be made by a commercially available measurement device on the basis of a laser light scattering type in-liquid particle measuring method using a laser as a light source. The particle diameter means a light scattering equivalent diameter with reference to a PSL (polystyrene latex) standard particle.

Herein, the term “particles” include not only particles such as dust, dirt, organic solid matter and inorganic solid matter contained as impurities in the raw materials but also particles such as dust, dirt, organic solid matter and inorganic solid matter introduced as contaminants during preparation of the liquid chemical, and refer to particles finally present without being dissolved in the liquid chemical.

Furthermore, it is preferable that the amount of respective Na, Mg, K, Ca, Mn, Fe, Cu, Li, Al, Cr, Ni, Zn and Ag elements (as metal impurity elements) in the liquid chemical is 0.1 mass ppb or less based on the total amount of the liquid chemical. When the amount of the metal impurity elements in the liquid chemical exceeds 0.1 mass ppb based on the total amount of the liquid chemical, there unfavorably occurs a risk of increase in device junction leakage current. This leakage current increase can lead to a deterioration in device yield and reliability. When the amount of the metal impurity elements in the liquid chemical is 0.1 mass ppb or less based on the total amount of the liquid chemical, it is favorably possible to omit or reduce the cleaning of the wafer surface (that is, the surface of the protective film) with a solvent or water after the formation of the protective film on the wafer surface. For this reason, it is preferable that the amount of the metal impurity elements in the liquid chemical is as small as possible. The amount of each of the metal impurity elements in the liquid chemical may however be 0.001 mass ppb or more as long as within the above range.

2. Water-Repellent Protective Film

In the present invention, the water-repellent protective film refers to a film formed on a wafer surface to decrease the wettability of the wafer surface, that is, impart water repellency to the wafer surface. The term “water repellency” as used herein means decreasing a surface energy of an article surface and thereby reducing an interaction such as hydrogen bond or intermolecular force (at an interface) between water or another liquid and the article surface. The water repellency provides a great interaction reducing effect against water, and provides a certain interaction reducing effect against a mixed liquid of water and a liquid other than water or against a liquid other than water. The contact angle of a liquid to an article surface can be increased with reduction of the interaction between the liquid and the article surface. Herein, the water-repellent protective film may be formed of the silicon compound or may include a reaction product containing the silicon compound as a predominant component.

3. Wafer Examples of the wafer include those each having formed on a surface thereof a film which contains a silicon element in the form of silicon, silicon oxide, silicon nitride etc. and those in which, when an uneven pattern is formed, at least a part of the uneven pattern contains a silicon element in the form of silicon, silicon oxide, silicon nitride etc. Even in the case of using a wafer composed of multiple components containing at least a silicon element, the protective film is applicable to a surface of the silicon element-containing component. Examples of such a multiple-component wafer include those each having a surface on which a silicon element-containing component such as silicon, silicon oxide, silicon nitride etc. is provided and those in which, when an uneven pattern is formed, at least a part of the uneven pattern contains a silicon element-containing component such as silicon, silicon oxide, silicon nitride etc. It is herein noted that the area of the wafer where the protective film can be formed from the protective film-forming agent in liquid form or the protective film-forming liquid chemical is a surface of the silicon element-containing part of the wafer.

In general, a wafer having a fine uneven pattern on a surface thereof is obtained by the following procedure. First, a resist is applied to a smooth surface of the wafer. Next, the applied resist is exposed to light through a resist mask. Exposed portions or unexposed portions of the resist are removed by etching, thereby forming the resist with a desired uneven pattern. The resist with the uneven pattern may alternatively be formed by pressing a mold with a pattern against the resist. Then, the wafer is subjected to etching. In this etching step, portions of the wafer surface corresponding to the recess portions of the resist pattern is selectively etched. Finally, the resist is removed. As a result, there is obtained the wafer with the fine uneven pattern.

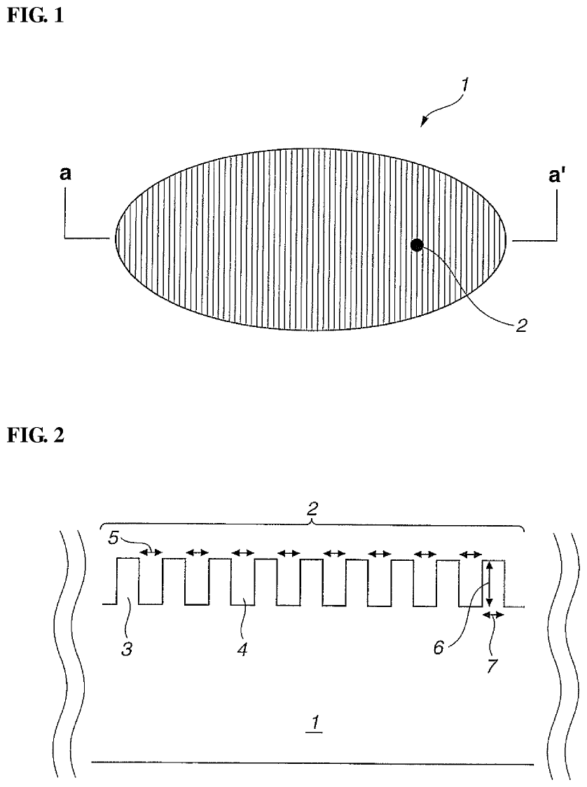

After the formation of the fine uneven pattern on the wafer surface, the wafer surface is cleaned with a water-based cleaning liquid; and the water-based cleaning liquid is removed from the wafer surface by drying or the like. During such cleaning process, a pattern collapse is likely to occur in the pattern when the width of recess portions of the pattern is small and the aspect ratio of projection portions of the pattern is high. The dimensions of the uneven pattern are defined as shown in FIGS. 1 and 2. FIG. 1 is a schematic perspective view of a wafer 1 having on a surface thereof a fine uneven pattern 2. FIG. 2 is a view showing a part of a-a′ cross section of FIG. 1. As shown in FIG. 2, a width 5 of the recess portions is determined as an interval between adjacent projection portions 3; and an aspect ratio of the projection portions is determined by dividing a height 6 of the projection portions by a width 7 of the projection portions. The pattern collapse tends to occur during the cleaning process when the width of the recess portions is 70 nm or smaller, particularly 45 rim or smaller; and the aspect ratio of the projection portions is 4 or higher, particularly 6 or higher.

4. Surface Treatment of Wafer

The wafer, on which the fine uneven pattern has been formed by etching as mentioned above, may be cleaned with a water-based cleaning liquid so as to remove etching residues in advance of the surface treatment of the wafer according to the present invention. The wafer may be further cleaned by replacing the water-based cleaning liquid remaining in the recess portions after the above cleaning process with a cleaning liquid different from the water-based cleaning liquid (hereinafter referred to as “cleaning liquid A”).

As the water-based cleaning liquid, there can be used water or an aqueous solution containing in water at least one kind selected from organic solvent, hydrogen peroxide, ozone, acid, alkali and surfactant (e.g. with a water content of 10 mass % or more).

As the cleaning liquid A, there can be used an organic solvent, a mixture of an organic solvent and a water-based cleaning liquid, or a cleaning liquid containing at least one kind selected from acid, alkali and surfactant in the organic solvent or in the mixture of the organic solvent and the water-based cleaning liquid.

In the present invention, there is no particular limitation on the technique for treatment of the wafer as long as the treatment is performed with the use of a cleaning machine by which the protective film-forming agent in liquid form, the protective film-forming liquid chemical or the cleaning liquid is retained in at least the recess portions of the uneven pattern of the wafer. As the wafer treatment technique, it is feasible to adopt a single wafer process using a spin treatment machine in which wafers are treated one by one by rotating the wafer in a nearly horizontal position while supplying the liquid to the vicinity of the rotation center, or a batch process in which a plurality of wafers are treated by immersing the wafers in the liquid within a chamber or by supplying a steam or mist of the liquid to the wafers within a chamber. There is no particular limitation on the form of the protective film-forming agent, the protective film-forming liquid chemical or the cleaning liquid supplied to at least the recess portions of the uneven pattern of the wafer as long as the protective film-forming agent, the protective film-forming liquid chemical or the cleaning liquid is in a liquid state when retained in the recess portions. The protective film-forming agent, the protective film-forming liquid chemical or the cleaning liquid can be supplied in e.g. liquid form or vapor form.

Examples of the organic solvent preferably usable as the cleaning liquid A include hydrocarbons, esters, ethers, ketones, halogen-containing solvents, sulfoxide-based solvents, lactone-based solvents, carbonate-based solvents, alcohols, polyol derivatives, nitrogen-containing solvents and the like.

In the present invention, the protective film-forming agent in liquid form or the protective film-forming liquid chemical is used by replacing the water-based cleaning liquid or cleaning liquid A with the agent or liquid chemical. The replaced agent or liquid chemical may be further replaced with a cleaning liquid different from the agent or liquid chemical (hereinafter referred to as “cleaning liquid B”).

After the cleaning of the wafer with the water-based cleaning liquid or cleaning liquid A, the cleaning liquid is replaced with the protective film-forming agent in liquid form or the protective film-forming liquid chemical as mentioned above. While the agent or liquid chemical is retained in at least the recess portions of the uneven pattern, the protective film is formed on at least the surface of the recess portions of the uneven pattern. In the present invention, the protective film is not necessarily continuously formed and is not necessarily uniformly formed. It is however preferable that the protective film is continuously and uniformly formed to impart higher water repellency.

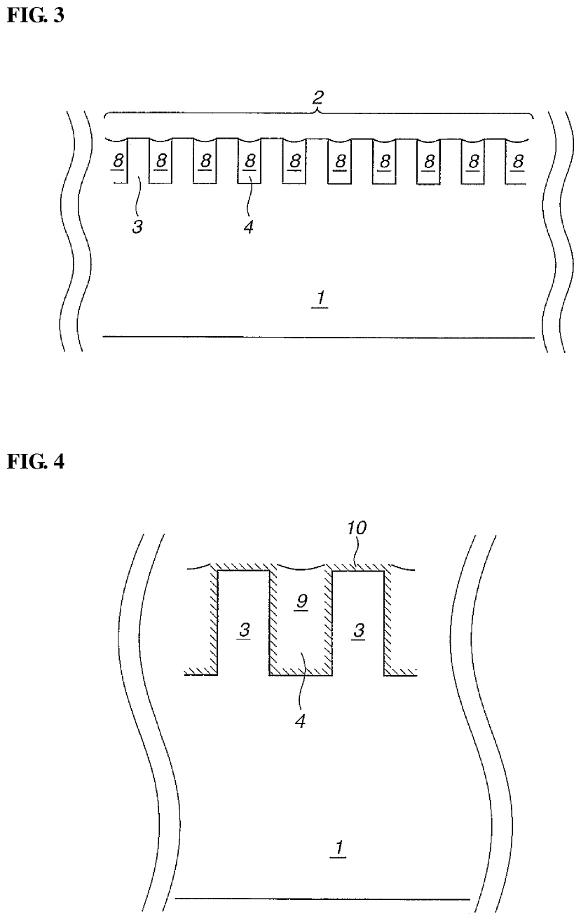

FIG. 3 is a schematic view showing a state where the protective film-forming agent in liquid form or protective film-forming liquid chemical 8 is retained in the recess portions 4. The schematic view of FIG. 3 corresponds to a part of the a-a′ cross section of FIG. 1. In this state, the protective film is formed on the surface of the recess portions 4 so that the surface of the recess portions 4 is made water repellent.

As the temperature of the protective film-forming agent in liquid form or the protective film-forming liquid chemical is increased, it becomes easy to form the protective film in a shorter time. The temperature at which the uniform protective film can be easily formed from the agent or liquid chemical is higher than or equal to 10° C. and lower than a boiling point of the agent or liquid chemical. In particular, the agent or liquid chemical is preferably retained at a temperature higher than or equal to 15° C. and lower than or equal to a temperature 10° C. lower than the boiling point of the agent or liquid chemical. It is preferable to maintain the temperature of the protective film-forming agent in liquid form or the protective film-forming liquid chemical at the above-mentioned temperature even while the agent or liquid chemical is retained in at least the recess portions of the uneven pattern. Herein, the boiling point of the protective film-forming liquid chemical means a boiling point of any component present in the largest amount by mass ratio among the components of the liquid chemical.

After the formation of the protective film, the protective film may be subjected to drying subsequent to the replacement of the protective film-forming agent or liquid chemical remaining in at least the recess portions of the uneven pattern with the cleaning liquid B. As the cleaning liquid B, there can be used a water-based cleaning liquid, an organic solvent, a mixture of a water-based cleaning liquid and an organic solvent with or without at least one kind selected from acid, alkali and surfactant, or a mixture thereof with the protective film-forming agent or liquid chemical. In terms of the removal of particles and metal impurities, the cleaning liquid B is preferably water, an organic solvent or a mixture of an organic solvent and water.

Examples of the organic solvent preferably usable as the cleaning liquid B include hydrocarbons, esters, ethers, ketones, halogen-containing solvents, sulfoxide-based solvents, alcohols, polyol derivatives, nitrogen-containing solvents and the like.

There are cases where, when the organic solvent is used as the cleaning liquid B, the protective film formed on the wafer surface from the protective film-forming agent in liquid form or the protective film-forming liquid chemical is less likely to be deteriorated in water repellency by cleaning with the cleaning liquid B.

FIG. 4 is a schematic view showing a state where a liquid is retained in the recess portions 4 to which water repellency has been imparted by the protective film-forming agent in liquid form or the protective film-forming liquid chemical. The schematic view of FIG. 4 corresponds to a part of a-a′ cross section of FIG. 1. The surface of the uneven pattern is made water repellent as the protective film 10 has been formed from the protective film-forming agent in liquid form or the protective film-forming liquid chemical on the surface of the uneven pattern. Even when the liquid 9 is removed from the uneven pattern, the protective film 10 is maintained on the wafer surface.

It is herein assumed that, in a state where the protective film 10 has been formed from the protective film-forming agent in liquid form or the protective film-forming liquid chemical on at least the surface of the recess portions of the uneven pattern of the wafer, water is retained on the surface of the recess portions. In this state, the contact angle of the water to the surface is preferably 50 to 130° so that a pattern collapse is made less likely to occur. The larger the contact angle, the higher the water repellency. Thus, the contact angle is more preferably 60 to 130°, still more preferably 65 to 130°. In addition, it is preferable that a decrease of the contact angle before and after the cleaning with the cleaning liquid B (i.e. the contact angle before the cleaning with the cleaning liquid B—the contact angle after the cleaning with the cleaning liquid B) is 10° or less.

The liquid retained in the recess portions 4 on which the protective film 10 has been formed from the protective film-forming agent in liquid form or the protective film-forming liquid chemical is removed by drying. The liquid retained in the recess portions may be the protective film-forming agent in liquid form, the protective film-forming liquid chemical, the cleaning liquid B or a mixed liquid thereof. The mixed liquid is a mixture of the protective film-forming agent and the cleaning liquid B or a composition in which the components of the protective film-forming liquid chemical are contained at lower concentrations than in the liquid chemical. Accordingly, the mixed liquid may be a liquid formed in the middle of replacing the protective film-forming agent in liquid form or the protective film-forming liquid chemical with the cleaning liquid B or may be a liquid prepared in advance by mixing the silicon compound into the cleaning liquid B. In terms of the cleanliness of the wafer, water, the organic solvent or a mixture thereof is preferred. After the liquid is once removed from the surface of the uneven pattern, the cleaning liquid B may be retained on the surface of the uneven pattern and then removed by drying.

In the case of cleaning the wafer with the cleaning liquid B after the formation of the protective film, the cleaning time, that is, the time of retaining the cleaning liquid B is preferably 10 seconds or longer, more preferably 20 seconds or longer, in terms of the removal of the particles or impurities from the surface of the uneven pattern. From the viewpoint of the water repellency maintaining effect of the protective film on the uneven pattern, there is a tendency that, when the organic solvent is used as the cleaning liquid B, the water repellency of the wafer surface can be easily maintained even after the cleaning. On the other hand, the productivity of the wafer is deteriorated when the cleaning time is too long. The cleaning time is thus preferably 15 minutes or shorter.

By the drying, the liquid retained in the uneven pattern is removed. It is preferable to perform the drying by a known drying process such as spin drying, WA (2-propanol) steam drying, Marangoni drying, heat drying, hot-air drying, air-blow drying or vacuum drying.

The protective film 10 may be removed after the drying. For removal of the water-repellent protective film, it is effective to cleave C—C bond and C—F bond in the water-repellent protective film. There is no particular limitation on the bond cleavage technique as long as it is capable of cleaving the above-mentioned bond. For example, it is feasible to treat the wafer surface by light irradiation, heating, ozone exposure, plasma irradiation, corona discharge or the like.

In the case of removing the protective film 10 by light irradiation, it is preferable to irradiate the protective film with ultraviolet light of wavelengths shorter than 340 nm and 240 nm, which respectively correspond to 83 kcal/mol and 116 kcal/mol, i.e., the bond energies of C—C bond and C—F bond in the protective film 10. As a light source, there can be used a metal halide lamp, a low-pressure mercury lamp, a high-pressure mercury lamp, an excimer lamp, a carbon arc lamp or the like. In the case of using a metal halide lamp, the irradiation intensity of the ultraviolet light is preferably 100 mW/cm² or higher, more preferably 200 mW/cm² or higher, as measured by an illuminometer (such as an irradiation intensity meter UM-10 manufactured by Konica Minolta Sensing, Inc. with a light receptor UM-360 (peak sensitivity wavelength: 365 nm, measurement wavelength range: 310 to 400 nm)). When the irradiation intensity is lower than 100 mW/cm², it takes a long time to remove the protective film 10. It is preferable to use the low-pressure mercury lamp because the low-pressure mercury lamp emits ultraviolet light of shorter wavelengths so as to, even if the irradiation intensity is low, remove the protective film 10 in a short time.

In the case of removing the protective film 10 by light irradiation, it is preferable to generate ozone in parallel with decomposing the constituent components of the protective film 10 by irradiation with ultraviolet light and then induce oxidation volatilization of the constituent components of the protective film 10 by the ozone for shortening of the treatment time. In this case, there can be used a low-pressure mercury lamp, an excimer lamp etc. as a light source. The wafer may be heated while being subjected to light irradiation.

In the case of heating the wafer, the heating temperature of the wafer is preferably 400 to 1000° C., more preferably 500 to 900° C.; and the heating time of the wafer is preferably 10 seconds to 60 minutes, more preferably 30 seconds to 10 minutes. The heating may be done in combination with ozone exposure, plasma irradiation, corona discharge or the like. The wafer may be subjected to light irradiation while heating.

As the technique of removing the protective film 10 by heating, it is feasible to bring the wafer into contact with a heat source or to place the wafer in a heated atmosphere such as heat treatment furnace. The placement of the wafer in the heated atmosphere is industrially advantageous in terms of easy treatment operation, short treatment time and high treatment capability because, even in the case of treating a plurality of wafers, the energy for removal of the protective film 10 can be applied uniformly to the respective wafer surfaces by the placement of the wafers in the heated atmosphere.

In the case of exposing the wafer to ozone, it is preferable to supply the wafer surface with ozone generated by ultraviolet radiation from a low-pressure mercury lamp etc., low-temperature discharge under high voltage application, or the like. The wafer may be subjected to light irradiation or heating while being exposed to ozone.

The protective film on the wafer surface can be efficiently removed by any combination of the light irradiation treatment, the heating treatment, the ozone exposure treatment, the plasma irradiation treatment and the corona discharge treatment.

### EXAMPLES

The present invention will be described in more detail below by way of the following embodiment examples. It should however be understood that the present invention is not limited to the following embodiment examples.

A method of forming an uneven pattern on a surface of a wafer and a method of replacing a cleaning liquid retained in at least recess portions of the uneven pattern with another cleaning liquid have been variously studied as in other literatures and have already been established. Accordingly, evaluations were made about the water repellency imparting effect of the protective film-forming agent in liquid form or the protective film-forming liquid in the present invention. In the following examples, water, which is known as a typical water-based cleaning liquid, was used as a liquid brought into contact with a surface of a wafer for contact angle evaluations.

In the case of a wafer having a fine uneven pattern on a surface thereof, however, it is not possible to exactly evaluate the contact angle of water to a protective film 10 itself formed on the uneven pattern.

The contact angle of a water drop is generally evaluated by dropping several microliters of water on a surface of a sample (substrate) and measuring an angle between the water drop and the substrate surface according to JIS R 3257 “Testing Method of Wettability of Glass Substrate Surface”. In the case of the wafer having the pattern, the contact angle is enormously large. This is due to the Wenzel's effect or Cassie's effect by which the apparent contact angle of the water drop becomes increased under the influence of the substrate surface shape (roughness) the contact angle.

In view of the above facts, the embodiment examples were each carried out by providing a wafer with a smooth surface, supplying a protective film-forming agent in liquid form or a protective film-forming liquid chemical to the smooth surface of the wafer to form a protective film on the wafer surface, and then, making various evaluations on the assumption of the thus-formed protective film as a protective film formed on an uneven pattern of a wafer. In each of the embodiment examples, a silicon wafer having a smooth surface coated with a SiO₂ layer, called a “SiO₂-coated wafer”, was used as the wafer with the smooth surface.

Hereinafter, detailed explanations will be given of methods of evaluations, a method of preparing a protective film-forming liquid chemical, a method of surface-treating a wafer with a protective film-forming agent in liquid form or a protective film-forming liquid chemical, and results of evaluations.

[Methods of Evaluations]

(A) Evaluation of Contact Angle to Protective Film on Wafer Surface

About 2 μl of pure water was dropped on a surface of a wafer on which a protective film was formed. In this state, the angle between the water drop and the wafer surface (as a contact angle) was measured with a contact angle meter (manufactured by Kyowa Interface Science Co., Ltd.: CA-X Model).

(B) Evaluation of Solid Deposit on Charging Port of Waste Liquid Container

After the surface treatment of a wafer with a water-repellent protective film-forming agent in liquid form or a water-repellent protective film-forming liquid chemical, the agent in liquid form or the liquid chemical was recovered (as a waste liquid) in a waste liquid container. The waste liquid container was left still, with a lid thereof open, for 1 day in a draft chamber where the ambient temperature was maintained at 25° C.; and the humidity was maintained at 50% RH. After that, the state of a solid deposit on a charging port of the waste liquid container was visually observed.

In the waste liquid, the amount of by-product is increased as the silicon compound accepts a proton from a silanol group during the surface treatment of the wafer or from the cleaning liquid such as iPA. It is particularly expected that, in the vicinity of the charging port of the waste liquid container, the silicon compound further accepts a proton from moisture (H₂O) of the air so that the by-product becomes likely to be deposited. When the by-product is solid, it is naturally likely that the solid deposit will be formed on the charging port of the waste liquid container. From the viewpoint of preventing pollution of the ambient environment by dust, it is preferable that there is formed no solid deposit.

### Example 1

(1) Preparation of Protective Film-Forming Liquid Chemical

In a globe box where the ambient temperature was set to 25° C., 2-trimethylsilyl-1,1,3,3-tetramethylguanidine ((CH₃)₂N—C(═N—Si(CH₃)₃)—N(CH₃)₂) as a silicon compound was dissolved at a concentration of 0.2 mass % in propylene glycol monomethyl ether acetate (hereinafter referred to as “PGMEA”) as an organic solvent under an atmosphere of 1.0 atm of nitrogen. There was thus obtained a protective film-forming liquid chemical.

Based on the total amount of the raw materials: PGMEA and 2-trimethylsilyl-1,1,3,3-tetramethylguanidine, the total amount of water contained in PGMEA and 2-trimethylsilyl-1,1,3,3-tetramethylguanidine was 10 mass ppm.

(2) Cleaning of Silicon Wafer

A silicon wafer with a smooth thermal oxide film (more specifically, a silicon wafer having on a surface thereof a thermal oxide film of 1 μm thickness) was immersed in an aqueous solution of 1 mass % hydrogen fluoride at 25° C. for 10 minutes, immersed in pure water at 25° C. for 1 minute and then immersed in 2-propanol (iPA) at 25° C. for 1 minute.

(3) Surface Treatment of Silicon Wafer with Protective Film-Forming Liquid Chemical

The above-cleaned silicon wafer was immersed, at 25° C. for 1 minute, in the protective film-forming liquid chemical that had been prepared in the above section “(1) Preparation of Protective Film-Forming Liquid Chemical”. The silicon wafer was further immersed in iPA at 25° C. for 1 minute and immersed in pure water at 25° C. for 1 minute. Finally, the silicon wafer was taken out from the pure water and dried by air blowing to remove the pure water from the surface of the silicon wafer.

The thus-obtained wafer was evaluated. As shown in TABLE 1, the initial contact angle before the surface treatment was less than 10°; and the contact angle after the surface treatment was 85°. It is thus apparent that a water repellency imparting effect was exerted in this Example. Further, the cleanliness of the charging port of the waste liquid container was maintained high because there was observed no solid deposit.

TABLE 1

| | Protective Film-Forming Liquid Chemical | | | |
|---|---|---|---|---|
| | | | | Total Water Amount |
| | | | | [mass ppm] in Silicon |
| | | | | Compound and Organic |
| | | | | Solvent Based on Total |
| | | | | Amount of Silicon |
| | Silicon Compound | | Organic | Compound and Organic |
| | | Conc. | Solvent | Solvent Before Preparation |
| | Kind | [mass %] | Kind | of Liquid Chemical |
| Ex. 1 | (CH₃)₂N—C(═N—Si[CH₃]₃)—N(CH₃)₂ | 0.2 | PGMEA | 10 |
| Ex. 2 | (CH₃)₂N—C(═N—Si[CH₃]₃)—N(CH₃)₂ | 0.03 | PGMEA | 10 |
| Ex. 3 | (CH₃)₂N—C(═N—Si[CH₃]₃)—N(CH₃)₂ | 0.05 | PGMEA | 10 |
| Ex. 4 | (CH₃)₂N—C(═N—Si[CH₃]₃)—N(CH₃)₂ | 0.5 | PGMEA | 10 |
| Ex. 5 | (CH₃)₂N—C(═N—Si[CH₃]₃)—N(CH₃)₂ | 1 | PGMEA | 10 |
| Ex. 6 | (CH₃)₂N—C(═N—Si[CH₃]₃)—N(CH₃)₂ | 3 | PGMEA | 10 |
| Ex. 7 | (CH₃)₂N—C(═N—Si[CH₃]₃)—N(CH₃)₂ | 5 | PGMEA | 10 |
| Ex. 8 | (CH₃)₂N—C(═N—Si[CH₃]₃)—N(CH₃)₂ | 1 | DnBE | 10 |
| Ex. 9 | (CH₃)₂N—C(═N—Si[CH₃]₃)—N(CH₃)₂ | 1 | DiAE | 10 |
| Ex. 10 | (CH₃)₂N—C(═N—Si[CH₃]₃)—N(CH₃)₂ | 1 | butyl acetate | 50 |
| Ex. 11 | (CH₃)₂N—C(═N—Si[CH₃]₃)—N(CH₃)₂ | 1 | decane | 100 |
| Ex. 12 | (CH₃)₂N—C(═N—Si[CH₃]₃)—N(CH₃)₂ | 1 | PGMEA | 100 |
| Ex. 13 | (CH₃)₂N—C(═N—Si[CH₃]₃)—N(CH₃)₂ | 1 | PGMEA | 300 |
| Ex. 14 | (CH₃)₂N—C(═N—Si[CH₃]₃)—N(CH₃)₂ | 1 | PGMEA | 500 |
| Ex. 15 | (Ph)HN—C(═N—Si[CH₃]₃)—NH(Ph) | 1 | PGMEA | 10 |

| | Evaluation Results | | | | |
|---|---|---|---|---|---|
| | | (A) | | | (B) |
| | Initial | Contact | By-Product | | Solid Deposit on |
| | Contact | Angle [°] | | Form | Charging Port of |
| | Angle | After Surface | | at 25° C. | Waste Liquid |
| | [°] | Treatment | Kind | and 1 atm | Container |
| Ex. 1 | <10 | 85 | (CH₃)₂N—C(═N—H)—N(CH₃)₂ | liquid | not visually |
| | | | | | observed |
| Ex. 2 | <10 | 63 | (CH₃)₂N—C(═N—H)—N(CH₃)₂ | liquid | not visually |
| | | | | | observed |
| Ex. 3 | <10 | 75 | (CH₃)₂N—C(═N—H)—N(CH₃)₂ | liquid | not visually |
| | | | | | observed |
| Ex. 4 | <10 | 87 | (CH₃)₂N—C(═N—H)—N(CH₃)₂ | liquid | not visually |
| | | | | | observed |
| Ex. 5 | <10 | 88 | (CH₃)₂N—C(═N—H)—N(CH₃)₂ | liquid | not visually |
| | | | | | observed |
| Ex. 6 | <10 | 91 | (CH₃)₂N—C(═N—H)—N(CH₃)₂ | liquid | not visually |
| | | | | | observed |
| Ex. 7 | <10 | 90 | (CH₃)₂N—C(═N—H)—N(CH₃)₂ | liquid | not visually |
| | | | | | observed |
| Ex. 8 | <10 | 87 | (CH₃)₂N—C(═N—H)—N(CH₃)₂ | liquid | not visually |
| | | | | | observed |
| Ex. 9 | <10 | 87 | (CH₃)₂N—C(═N—H)—N(CH₃)₂ | liquid | not visually |
| | | | | | observed |
| Ex. 10 | <10 | 88 | (CH₃)₂N—C(═N—H)—N(CH₃)₂ | liquid | not visually |
| | | | | | observed |
| Ex. 11 | <10 | 87 | (CH₃)₂N—C(═N—H)—N(CH₃)₂ | liquid | not visually |
| | | | | | observed |
| Ex. 12 | <10 | 87 | (CH₃)₂N—C(═N—H)—N(CH₃)₂ | liquid | not visually |
| | | | | | observed |
| Ex. 13 | <10 | 80 | (CH₃)₂N—C(═N—H)—N(CH₃)₂ | liquid | not visually |
| | | | | | observed |
| Ex. 14 | <10 | 70 | (CH₃)₂N—C(═N—H)—N(CH₃)₂ | liquid | not visually |
| | | | | | observed |
| Ex. 15 | <10 | 72 | (Ph)HN—C(═N—H)—NH(Ph) | solid | slightly visually |
| | | | | | observed |

### Examples 2 to 15

The surface treatment of wafers was performed in the same manner as in Example 1, except that liquid chemical preparation conditions such as the kind of the silicon compound, the kind of the organic solvent, the concentration of the silicon compound and the total amount of water in the raw materials were changed. Then, the surface-treated wafers were evaluated. The results are shown in TABLE 1.

In the table, the abbreviation “DnBE” refers to di-normal butyl ether; the abbreviation “DiAE” refers to diisoamyl ether; and the chemical formula (Ph)HN—C(═N—Si(CH₃)₃)—NH(Ph) refers to 2-trimethylsilyl-1,3-diphenylguanidine as a silicon compound.

In each of these Examples, a water repellency imparting effect was exerted as is apparent from the results that: the initial contact angle before the surface treatment was less than 10°; and the contact angle was improved after the surface treatment. It is confirmed from the results of Examples 5 and 12 to 14 that the smaller the total amount of water contained in the water-repellent protective film-forming agent (silicon compound) and the organic solvent based on the total amount of the water-repellent protective film-forming agent and the organic solvent before the preparation of the water-repellent protective film-forming liquid chemical, the better the water repellency imparting effect. Furthermore, the solid deposit was slightly observed in Example 15 in which the by-product compound formed upon the acceptance of a proton by the silicon compound was solid; whereas the solid deposit was not observed in Example 5 in which the by-product compound formed upon the acceptance of a proton by the silicon compound was liquid. It is apparent from the results of Examples 5 and 15 that the cleanliness of the charging port of the waste liquid container was higher in Example 5.

### Comparative Example 1

The surface treatment of a wafer was performed in the same manner as in Example 1, except that liquid chemical preparation conditions such as the kind and concentration of the silicon compound were changed as shown in TABLE 2. Then, the surface-treated wafer was evaluated. In Comparative Example 1, the raw materials in TABLE 2 refer to the silicon compound and the organic solvent before the preparation of the liquid chemical.

Herein, Comparative Example 1 corresponds to an experimental example using the protective film-forming liquid chemical in which trimethylmethoxysilane was used in place of 2-trimethylsilyl-1,1,3,3-tetramethylguanidine. The contact angle after the surface treatment was at a small degree of less than 10°. Thus, a water repellency imparting effect was not exerted in this Comparative Example.

TABLE 2

| | Protective Film-Forming Liquid Chemical | | | | Evaluation Results | |
|---|---|---|---|---|---|---|
| | Raw Starting Materials | | | | Initial | Contact |
| | Silicon Compound | | Organic | Total Water Amount [mass ppm] | Contact | Angle [°] |
| | | Conc. | Solvent | in Raw Materials Based on | Angle | After Surface |
| | Kind | [mass %] | Kind | Total Amount of Raw Materials | [°] | Treatment |
| Comp. Ex. 1 | (CH₃)₃Si—OCH₃ | 3 | decane | 10 | <10 | <10 |

| | | | | |
|---|---|---|---|---|
| Ref. Ex. 1 | Liquid chemical of 3 mass % (CH₃)₃SiCl in toluene | 50 | <10 | 65 |
| Ref. Ex. 2 | Liquid chemical of 3 mass % (CH₃)₃Si—OCH₃ and | 50 | <10 | 84 |
| | 1 mass % CF₃SO₃H in PGMEA | | | |

### Reference Examples 1 and 2

In Reference Examples, the surface treatment of wafers were performed in the same manner as in Example 1, except that protective film-forming liquid chemicals according to Examples of Patent Documents 1 and 2 were respectively used. Then, the surface-treated wafers were evaluated. The results are shown in TABLE 2.

More specifically, Reference Example 1 was carried out by reference to Example 22 of Patent Document 1, in which the protective film-forming liquid chemical was prepared by mixing 3 g of trimethylchlorosilane ((CH₃)₃SiCl) and 97 g of toluene together; and the wafer was surface-treated with the prepared liquid chemical. The contact angle after the surface treatment was 65°. Thus, a water repellency imparting effect was exerted in this Reference Example. In Reference Example 1, the raw materials in TABLE 2 refer to trimethylchlorosilane and toluene before the preparation of the liquid chemical.

Reference Example 2 was carried out by reference to Example 4 of Patent Document 2, in which the protective film-forming liquid chemical was prepared by mixing 3 g of trimethylmethoxysilane ((CH₃)₃Si—OCH₃), 1 g of trifluoromethanesulfonic acid (CF₃SO₃H) and 96 g of PGMEA together; and the wafer was surface-treated with the prepared liquid chemical. The contact angle after the surface treatment was 84°. Thus, a water repellency imparting effect was also exerted in this Reference Example. In Reference Example 2, the raw materials in TABLE 2 refer to trimethylmethoxysilane, trifluoromethanesulfonic acid and PGMEA before the preparation of the liquid chemical.

### Example 16

The surface treatment of a wafer was performed in the same manner as in Example 1, except that 2-trimethylsilyl-1,1,3,3-tetramethylguanidine was used as a protective film-forming agent in liquid form in place of the protective film-forming liquid chemical. Then, the surface-treated wafer was evaluated. Herein, 2-trimethylsilyl-1,1,3,3-tetramethylguanidine is liquid at 25° and 1.0 atmospheric pressure.

As a result, the initial contact angle before the surface treatment was less than 10°; and the contact angle after the surface treatment was 92°. It is thus apparent that a good water repellency imparting effect was exerted in this Example. Further, the cleanliness of the charging port of the waste liquid container was maintained high because there was observed no solid deposit.

The water repellency imparting effect of the water-repellent protective film-forming agent in liquid form or the water-repellent protective film-forming liquid chemical according to the present invention was equivalent to that of the protective film-forming liquid chemicals of the above-mentioned Reference Examples. Therefore, the novel protective film-forming agent or novel protective film-forming liquid chemical has been found, which exhibits a water repellency imparting effect equivalent to that of conventional protective-film forming liquid chemical, in which the water-repellent protective film-forming component contains no chlorine and which does not essentially require any protective film formation promoting component.

### DESCRIPTION OF REFERENCE NUMERALS

1: Wafer
2: Fine uneven pattern on wafer surface
3: Projection portion of pattern
4: Recess portion of pattern
5: Width of recess portion
6: Height of projection portion
7: Width of projection portion
8: Water-repellent protective film-forming agent in liquid form or
water-repellent protective film-forming liquid chemical retained in recess portion 4
9: Liquid retained in recess portion 4
10: Protective film

1. A water-repellent protective film-forming agent for forming a water-repellent protective film on a surface of a wafer, the surface of the wafer containing a silicon element, the water-repellent protective film-forming agent comprising at least one kind of silicon compound selected from the group consisting of guanidine derivatives of the following general formula [1] and amidine derivatives of the following general formula [2] 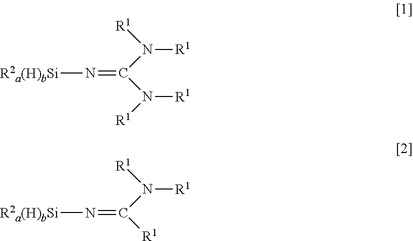
where R¹ is each independently a hydrogen atom, a —C≡N group, a —NO₂ group or a hydrocarbon group in which a part or all of hydrogen atoms may be substituted with a fluorine atom; the hydrocarbon group as R¹ may contain an oxygen atom and/or a nitrogen atom; R² is a monovalent hydrocarbon group of 1 to 18 carbon atoms in which a part or all of hydrogen atoms may be substituted with a fluorine atom; a is an integer of 1 to 3; b is an integer of 0 to 2; and the sum of a and b is 3.

2. The water-repellent protective film-forming agent according to claim 1, wherein b in the general formulas [1] and [2] is 0.

3. The water-repellent protective film-forming agent according to claim 2, wherein at least two of three R² in the general formulas [1] and [2] are methyl groups.

4. The water-repellent protective film-forming agent according to claim 1, wherein R¹ in the general formulas [1] and [2] is each independently selected from the group consisting of a hydrogen atom, an alkyl group of 1 to 6 carbon atoms and an alkoxy group of 1 to 6 carbon atoms.

5. The water-repellent protective film-forming agent according to claim 1, wherein a compound by-produced upon the acceptance of a proton by the silicon compound is liquid at 25° C. and 1.0 atmospheric pressure.

6. The water-repellent protective film-forming agent according to claim 1, wherein the silicon compound is of the general formula [1].

7. The water-repellent protective film-forming agent according to claim 6, wherein the silicon compound is of the general formula [1] where all of R¹ are methyl groups; a is 3; b is 0; two of three R² are methyl groups; and the remaining one of R² is a monovalent hydrocarbon groups of 1 to 18 carbon atoms in which a part or all of hydrogen atoms may be substituted with a fluorine atom.

8. A water-repellent protective film-forming liquid chemical comprising: the water-repellent protective film-forming agent according to claim 1; and an organic solvent.

9. The water-repellent protective film-forming liquid chemical according to claim 8, wherein the concentration of the water-repellent protective film-forming agent is 0.01 to 25 mass % based on 100 mass % of the total amount of the water-repellent protective film-forming agent and the organic solvent.

10. The water-repellent protective film-forming liquid chemical according to claim 8, wherein the organic solvent is an aprotic solvent.

11. The water-repellent protective film-forming liquid chemical according to claim 8, wherein the total amount of water contained in the water-repellent protective film-forming agent and the organic solvent before preparation of the water-repellent protective film-forming liquid chemical is 5000 mass ppm or less based on the total amount of the water-repellent protective film-forming agent and the organic solvent.

12. A method of surface-treating a silicon element-containing wafer with the water-repellent protective film-forming agent according to claim 1 in liquid form.

13. A method of surface-treating a silicon element-containing wafer with the water-repellent protective film-forming liquid chemical according to claim 8.
